(19) United States
(12) Patent Application Publication
(10) Pub. No.: US 2023/0058578 A1
(43) Pub. Date: Feb. 23, 2023

(54) HIGH-ASPECT RATIO METALLIZED STRUCTURES

(71) Applicant: GE PRECISION HEALTHCARE LLC, WAUWATOSA, WI (US)

(72) Inventors: Shubhodeep Goswami, Schenectady, NY (US); David Milford Shaddock, Troy, NY (US); Matthew David Butts, Rexford, NY (US); Gregory Keith Dudoff, Schenectady, NY (US)

(21) Appl. No.: 17/404,646

(22) Filed: Aug. 17, 2021

(51) Int. Cl. H01L 21/308; H01L 21/3065; G21K 1/06; B81C 1/00

(52) U.S. Cl. CPC H01L 21/3086; H01L 21/3065; G21K 1/067; B81C 1/00555

(57) ABSTRACT

The present techniques relate to various aspects of forming and filling high-aspect ratio trench structures (e.g., trench structures having an aspect ratio of 20 or greater, including aspect ratios in the range of 20:1 up to and including 50:1 or greater) combined with trench opening widths ranging from 0.5 micron to 50 microns. In one implementation a method to fabricate high-aspect ratio trenches in silicon is provided using a patterned photoresist on evaporated aluminum. In accordance with this approach, a high-aspect ratio trench can be formed having vertical side walls and defect-free trench bottoms. In some instances it may be desirable to fill such high-aspect ratio trench structures with a metal or other substrate to provide certain functionality associated with the fill material. Further processes and structures are related in which such trench structures are filled using a mixture of high-Z nano-particles within an epoxy resin matrix.

### BACKGROUND

Embodiments of the present specification relate generally to high-aspect ratio gratings, which may be used in various mechanical systems including imaging systems.

Various mechanical and micro-mechanical systems may employ gratings or grids that include some form of trench or other opening defined at least partially by sidewalls (e.g., vertical sidewalls). Such gratings or grids may be employed to limit or collimate the passage of energy or material from one side of the grating or grid to the opposite side or may perform other functions where the trench or other sidewall structures facilitate the functioning of the overall system.

In practice, a trench of such a structure may be characterized by an aspect ratio, which is the ratio of one dimension of the trench relative to another dimension of the trench. For example, an aspect ratio of such a trench may generally be equated to the ratio of the longer dimension (e.g., height) to the shorter dimension (e.g., width) of the trench. Thus, the taller and narrower the trench, the higher the aspect ratio of the trench.

In general, it may be difficult to pattern vertical sidewalls of such a trench beyond aspect ratios of 20 when combined with trench widths larger than 0.5 microns up to 50 microns in silicon using conventional photoresists. Metal masking may be employed but has been an imperfect solution due to re-sputtering and re-deposition of the metal into the etched regions and defects due to undesired micro-masking in the trench regions. In addition, in some contexts it may be useful to fill the trenches with a separate material (e.g., a metal). However, traditional methods to fill metal into deep or high-aspect ratio trenches typically involves expensive cleanroom based processing (e.g., electron-beam evaporation, electroplating, sputtering, and so forth).

### BRIEF DESCRIPTION

Certain embodiments commensurate in scope with the originally claimed subject matter are summarized below. These embodiments are not intended to limit the scope of the claimed subject matter, but rather these embodiments are intended only to provide a brief summary of possible embodiments. Indeed, the invention may encompass a variety of forms that may be similar to or different from the embodiments set forth below.

In one embodiment, a method is provided for forming a patterned substrate. In accordance with this method, a mask layer is deposited on a substrate. A photoresist layer is deposited on the mask layer. The photoresist layer is patterned to form a pattern. The mask layer is etched through the pattern to expose the substrate. The substrate is etched through the pattern to form a structure comprising a plurality of trenches having vertical sidewalls. The photoresist layer remains on the mask layer during etching of the substrate.

In a further embodiment, a method is provided for forming a metallized grid structure. In accordance with this method, a mixture of high-Z nano-particles and a carrier fluid that cures to a solid state is applied to a substrate comprising a plurality of trenches. The mixture is distributed into the plurality of trenches. Excess mixture not in the plurality of trenches is removed from the surface of the substrate. The carrier fluid is cured to the solid state to form the metallized grid structure.

In an additional embodiment, a grid structure is provided. In accordance with this embodiment, the grid structure comprises: a substrate in which a plurality of trenches are formed and a cured carrier fluid disposed within the plurality of trenches. A plurality of nano-particles are suspended within the cured carrier fluid.

### BRIEF DESCRIPTION OF THE DRAWINGS

These and other features, aspects, and advantages of the present invention will become better understood when the following detailed description is read with reference to the accompanying drawings in which like characters represent like parts throughout the drawings, wherein:

FIG. 1 depicts components of a computed tomography imaging system, in accordance with certain aspects of the present disclosure;

FIG. 2 depicts a flow diagram of steps of a process for forming high-aspect ratio trenches within a substrate, in accordance with certain aspects of the present disclosure;

FIG. 3 illustrates using a schematic and images, examples of high-aspect ratio trenches formed in accordance with certain aspects of the present disclosure;

FIG. 4 depicts a process flow of steps by which structures formed with high-aspect ratio trenches may be combined to form higher-aspect ratio trenches, in accordance with certain aspects of the present disclosure;

FIG. 5 depicts an additional process flow of steps by which structures formed with high-aspect ratio trenches may be combined to form an absorption grating structure having functionally higher-aspect ratio metallized trenches, in accordance with certain aspects of the present disclosure;

FIG. 6 depicts a flow diagram of steps of a process for filling trenches with a nano-particle mixture, in accordance with certain aspects of the present disclosure;

FIG. 7 depicts a cut-away view of nano-particle filled trenches, in accordance with certain aspects of the present disclosure;

FIG. 8 depicts an additional cut-away view of nano-particle filled trenches, in accordance with certain aspects of the present disclosure; and

FIG. 9 depicts a cut-away element view of nano-particle filled trenches, in accordance with certain aspects of the present disclosure.

### DETAILED DESCRIPTION

One or more specific embodiments will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present invention, the articles “a,” “an,” “the,” and “said” are intended to mean that there are one or more of the elements. The terms “comprising,” “including,” and “having” are intended to be inclusive and mean that there may be additional elements other than the listed elements. Furthermore, any numerical examples in the following discussion are intended to be non-limiting, and thus additional numerical values, ranges, and percentages are within the scope of the disclosed embodiments.

While aspects of the following discussion may be provided in the context of medical imaging (e.g., X-ray imaging gratings), it should be appreciated that the present techniques are not limited to such medical contexts. Indeed, the provision of examples and explanations in such a medical context is only to facilitate explanation by providing instances of real-world implementations and applications. However, the present approaches may also be utilized in other contexts in which high-aspect ratio sidewall structures (e.g., grids, trenched and/or segmented gratings, Micro-Electro-Mechanical Systems (MEMS) devices, and so forth) are employed. For example, the present techniques may be employed in the manufacture of capacitive MEMS devices, electrostatic MEMS devices, inertial MEMS devices, magnetic MEMS devices, electromagnetic MEMS devices, radiofrequency MEMS devices, and other MEMS structures, as well as Through Silicon Vias (TSVs), fin field-effect transistors (FinFETs), interconnect structures in system-on-a-chip (SOC) or complementary metal-oxide semiconductor (CMOS) devices, and so forth.

In general, it is difficult to pattern vertical sidewalls (such as may be present in formed trenches) having aspect ratios greater than 20 in combination with trench widths larger than 0.5 microns up to 50 microns in a substrate (such as a silicon substrate) using conventional photoresists. Approaches employing metal masking, for example, may result in re-sputtering and re-deposition of the metal into the etched regions and/or defects from undesired micro-masking in the trench regions.

The present techniques relate to various aspects of forming and filling high-aspect ratio trench structures (e.g., trench structures having an aspect ratio of 20 or greater, including aspect ratios in the range of 20:1 up to and including 50:1 or greater). By way of example, in one implementation a method to fabricate high-aspect ratio trenches in a substrate (such as a silicon substrate or wafer) is provided using a patterned photoresist on a mask layer (e.g., an evaporated aluminum mask layer), which acts as deep reactive ion etch mask during a Bosch process. In accordance with this approach, a high-aspect ratio trench can be formed having vertical side walls, very low re-sputtering of the mask material (e.g., aluminum metal), and with negligible micro-masking of the open trench regions.

In some instances it may be desirable to fill such high-aspect ratio trench structures with a metal or other substrate to provide certain functionality associated with the fill material. Traditional methods to fill metal into deep trench structures typically involve expensive cleanroom based processing (e.g., e-beam evaporation, electroplating, sputtering, atomic layer deposition, etc.).

With this in mind, a further aspect of the present techniques include filling metal into such high-aspect ratio trench structures using non-cleanroom additive approaches (e.g., squeegee, screen printing, or roll printing approaches). By way of example, the present techniques include approaches for filling high-aspect ratio trench structures with high atomic weight (i.e., high-Z) elements (e.g., materials having atomic numbers (i.e., Z values) of 72 and beyond, such as, but not limited to hafnium, tantalum, tungsten, rhenium, osmium, iridium, platinum, gold, mercury, thallium, lead, bismuth, polonium, depleted uranium, and so forth), though other elements, such as palladium, may also be employed in other embodiments. These techniques may allow for the formation of periodic metal gratings using novel and inexpensive nano-particle formulations through screen printing and roll printing. Such periodic high-aspect ratio metallized gratings are used in applications ranging from X-ray imaging for healthcare, X-ray inspection systems for materials analysis, X-ray lithography for nanofabrication of capacitive MEMs, micro-inductors, and so forth.

In one implementation nano-particles of high atomic weight elements (e.g., metal nano-particles) are dispersed in solvent matrices and screen printed and/or roll printed into pre-fabricated high-aspect ratio trenches with periods at the sub-20 μm scale. Screen printing and/or roll printing of these nano-particulate inks (or other nano-particle containing media) is readily scalable to any substrate size (e.g., wafers, panels, flexible rolls, and so forth) and to high volume production. Correspondingly, advantages of this technique relative to prior techniques include, but are not limited to, reduced processing step requirements, reduced equipment costs, higher throughput per unit area of substrate, flexible fabrication across whole range of nano-particle compositions, easier scalability across a range of aspect ratios and substrate sizes, and so forth.

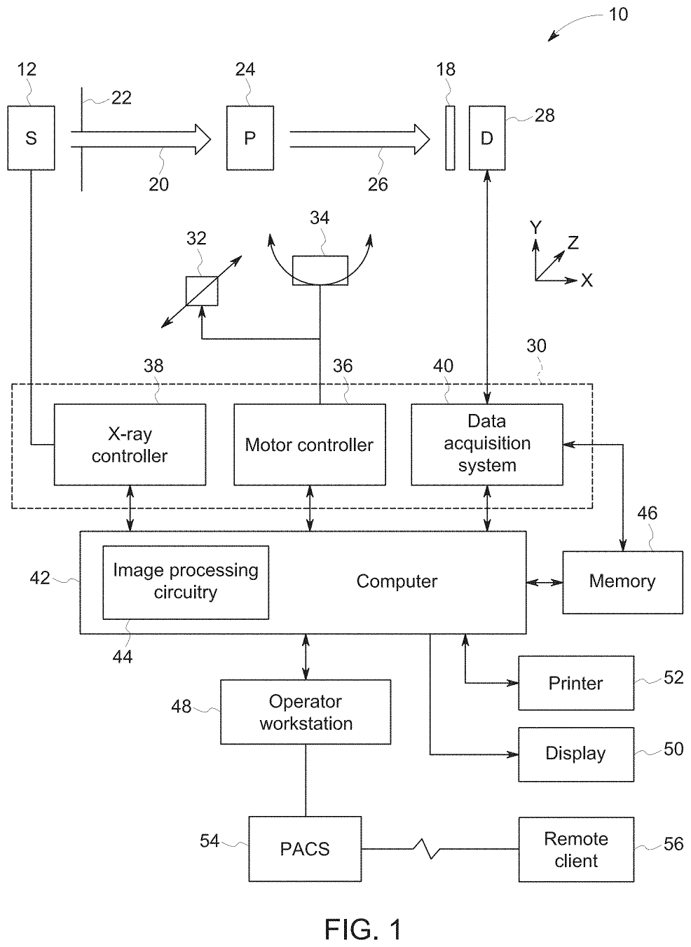

With the preceding discussion in mind, FIG. 1 illustrates an embodiment of an imaging system 10 for acquiring and processing image data in accordance with structures and approaches discussed herein. That is, the depicted type of imaging system 10 is an example of one type of imaging system that may benefit from or otherwise utilize components made in accordance with the techniques described herein (e.g., high-aspect ratio metallized gratings or grids). Though, as noted herein, other types of systems (e.g., non-imaging systems, non-medical systems, and so forth) may also utilize components made in accordance with the techniques described herein.

In the illustrated example, system 10 is a computed tomography (CT) system designed to acquire X-ray projection data and to reconstruct the projection data into volumetric reconstructions for display and analysis. The CT imaging system 10 includes one or more X-ray sources 12, such as one or more X-ray tubes or solid state emission structures which allow X-ray generation at one or more energy spectra during an imaging session.

In certain implementations, the source 12 may be positioned proximate to a pre-patient collimator and/or filter assembly 22 that may be used to steer the X-ray beam 20, to define the shape (such as by limiting off-angle emissions) and/or extent of a high-intensity region of the X-ray beam 20, to control or define the energy profile of the X-ray beam 20, and/or to otherwise limit X-ray exposure on those portions of the patient 24 not within a region of interest. In practice, the filter assembly or beam shaper 22 may be incorporated within the gantry, between the source 12 and the imaged volume.

The X-ray beam 20 passes into a region in which the subject (e.g., a patient 24) or object of interest (e.g., manufactured component, baggage, package, and so forth) is positioned. The subject attenuates at least a portion of the X-ray photons 20, resulting in attenuated X-ray photons 26 that impinge upon a pixelated detector array 28 formed by a plurality of detector elements (e.g., pixels) arranged in an array. In the depicted example, the attenuated X-ray photons 26 pass through a collimator 18 (e.g., an anti-scatter grid) prior to reaching the detector array 28. As discussed herein, the collimator 18 may consist of a plurality of blades or other elements aligned substantially perpendicular to the surface of the detector array 28 and formed from an attenuating material that limit or prevent X-ray photons 26 traveling at off-angles (e.g., scattered X-rays) from reaching the detector array 28. The electrical signals reaching the detector array 28 are detected and processed to generate one or more projection datasets. In the depicted example, the detector 28 is coupled to the system controller 30, which commands acquisition of the digital signals generated by the detector 28.

A system controller 30 commands operation of the imaging system 10 to execute filtration, examination and/or calibration protocols, and may process the acquired data. With respect to the X-ray source 12, the system controller 30 furnishes power, focal spot location, control signals and so forth, for the X-ray examination sequences. In accordance with certain embodiments, the system controller 30 may control operation of the filter assembly 22, the CT gantry (or other structural support to which the X-ray source 12 and detector 28 are attached), and/or the translation and/or inclination of the patient support over the course of an examination.

In addition, the system controller 30, via a motor controller 36, may control operation of a linear positioning subsystem 32 and/or a rotational subsystem 34 used to move the subject 24 and/or components of the imaging system 10, respectively. For example, in a CT system, the radiation source 12 and detector 28 rotate about the object (e.g., patient 24) to acquire X-ray transmission data over a range of angular views. Thus, in a real-world implementation, the imaging system 10 is configured to generate X-ray transmission data corresponding to each of the plurality of angular positions (e.g., 360°, 180°+a fan beam angle (a), and so forth) covering an entire scanning area of interest.

The system controller 30 may include signal processing circuitry and associated memory circuitry. In such embodiments, the memory circuitry may store programs, routines, and/or encoded algorithms executed by the system controller 30 to operate the imaging system 10, including the X-ray source 12 and/or filter assembly 22, and to process the digital measurements acquired by the detector 28. In one embodiment, the system controller 30 may be implemented as all or part of a processor-based system.

The source 12 may be controlled by an X-ray controller 38 contained within the system controller 30. The X-ray controller 38 may be configured to provide power, timing signals, and/or focal spot size and spot locations to the source 12. In addition, in some embodiments the X-ray controller 38 may be configured to selectively activate the source 12 such that tubes or emitters at different locations within the system 10 may be operated in synchrony with one another or independent of one another or to switch the source between different energy profiles during an imaging session.

The system controller 30 may include a data acquisition system (DAS) 40. The DAS 40 receives data collected by readout electronics of the detector 28, such as digital signals from the detector 28. The DAS 40 may then convert and/or process the data for subsequent processing by a processor-based system, such as a computer 42. In certain implementations discussed herein, circuitry within the detector 28 may convert analog signals of the detector to digital signals prior to transmission to the data acquisition system 40. The computer 42 may include or communicate with one or more non-transitory memory devices 46 that can store data processed by the computer 42, data to be processed by the computer 42, or instructions to be executed by image processing circuitry 44 of the computer 42. For example, a processor of the computer 42 may execute one or more sets of instructions stored on the memory 46, which may be a memory of the computer 42, a memory of the processor, firmware, or a similar instantiation. By way of example, the image processing circuitry 44 of the computer 42 may be configured to generate a diagnostic image.

The computer 42 may also be adapted to control features enabled by the system controller 30 (i.e., scanning operations and data acquisition), such as in response to commands and scanning parameters provided by an operator via an operator workstation 48. The system 10 may also include a display 50 coupled to the operator workstation 48 that allows the operator to view relevant system data, imaging parameters, raw imaging data, reconstructed data or images, and so forth. Additionally, the system 10 may include a printer 52 coupled to the operator workstation 48 and configured to print any desired measurement results. The display 50 and the printer 52 may also be connected to the computer 42 directly (as shown in FIG. 1) or via the operator workstation 48. Further, the operator workstation 48 may include or be coupled to a picture archiving and communications system (PACS) 54. PACS 54 may be coupled to a remote system or client 56, radiology department information system (RIS), hospital information system (HIS) or to an internal or external network, so that others at different locations can gain access to the image data.

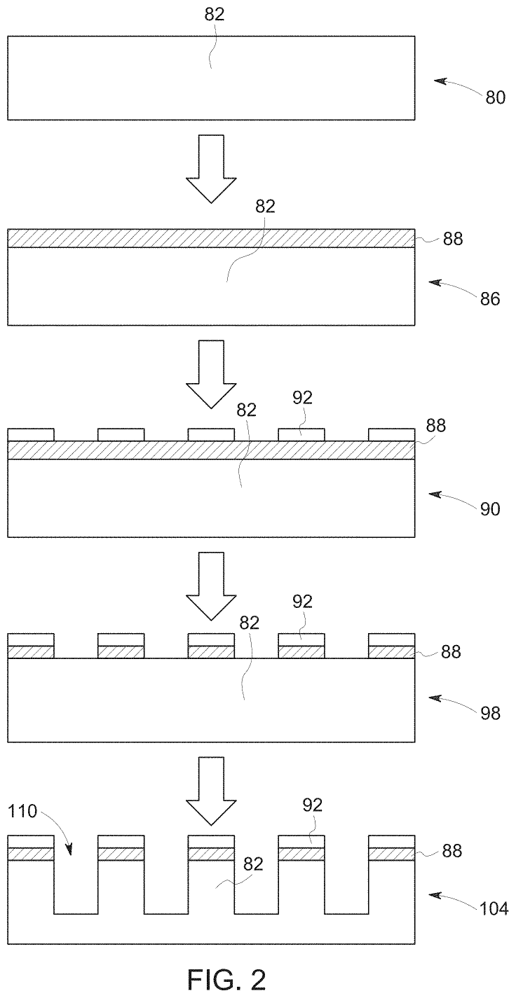

As noted above, certain features of the imaging system 10 (or other suitable system) may utilize components that include high aspect ratio trenches (metallized or otherwise) as part of their structure. For example, in the context of an imaging system, absorption gratings, phase gratings, anti-scatter features, collimation features, and so forth may include such trench structures and may benefit from higher aspect ratio trenches than what is conventionally possible. With the preceding discussion of an overall imaging system 10 in mind, and turning to FIG. 2, an example of an approach for forming high-aspect ratio trench structures is illustrated as a process flow.

In this example, a substrate (e.g., a silicon wafer, such as a standard (1,0,0) silicon wafer) undergoes a high-aspect ratio patterning process using a patterned resist and mask (e.g., an metal or other hard mask, such as an aluminum mask). For the purpose of illustration and explanation, the following example and other examples herein may be provided in the context of a silicon substrate or wafer and an aluminum mask so as to provide a real-world context. However it should be appreciated that such examples are for the purpose of illustration only, and that in practice any suitable substrate and/or mask may be employed. With this in mind, in one implementation, a deep reactive ion etch is performed on the silicon wafer. In step 80 of FIG. 2, a silicon wafer 82 is initially provided as part of the process. As step 86 aluminum is evaporated and then deposited onto the silicon wafer 82 as an aluminum layer 88, such as using electron beam (e-beam) evaporation. In one implementation, the aluminum layer 88 has a thickness of approximately 0.5 μm or greater. More generally, the thickness of the aluminum mask layer and photoresist may be determined based on the ratio of vertical etch rates of silicon being greater than that of aluminum and photoresist.

At step 90 a photoresist layer 92 is coated over the aluminum layer 88 and patterned (e.g., photolithographically patterned) to correspond to the trench structures to be formed, thereby forming the desired device layer. By way of example, this step may include some or all of the sub-steps of: spin-coating the photoresist layer 92 onto the aluminum layer 88, baking or otherwise setting the photoresist material on the substrate and removing any remaining solvent, exposing the photoresist material to some form of radiation to produce the desired pattern image on the layer of photoresist, and developing the photoresist pattern on the aluminum layer 88 based on the pattern image so as to form the physical pattern on the aluminum layer 88. In one such example of an implementation, the photoresist applied has a thickness of 7.5 μm or greater and is patterned to correspond to the trench structures to be formed.

At step 98 the aluminum layer 88 is wet etched through the pattern created by the photoresist layer 92. In this manner, the pattern of the photoresist layer 92 is applied to the aluminum layer 88 exposing the silicon 82 based upon the pattern. Lastly, at step 104, the silicon wafer stack 82 is processed in accordance with the pattern to form trenches 110. In one embodiment the silicon 82 is processed using deep reactive ion etch (DRIE) equipment, such as using a SF₆/C₄F₈/O₂ plasma (e.g., in accordance with a Bosch process), to form trenches 110 having a high-aspect ratio (e.g., an aspect ratio greater than or equal to 20:1, including greater than or equal to 25:1 30:1, 35:1, 40:1, 45:1, and so forth up to and including 50:1) and substantially vertical sidewall angles. In one such example, SF₆/C₄F₈ plasma may be suitable for performing the etch step because aluminum 88 and photoresist 92 have a lower vertical etch rate relative to silicon 82 using SF₆/C₄F₈ plasma, leaving the aluminum patterned layer 88 largely intact while the silicon 82 is etched. In addition, the photoresist layer 92 in this example protects the aluminum layer 88 from being exposed to the plasma on the upper surface, and thereby prevents re-sputtering and micro-masking of the trench bottoms and sidewalls during the initial phase of the etch.

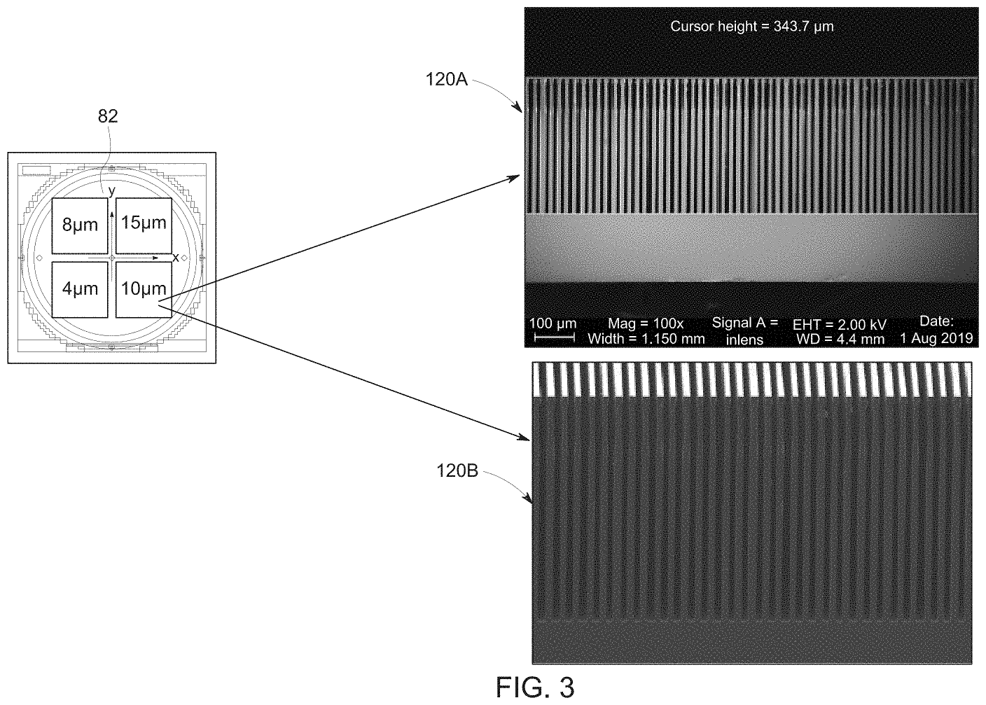

With the preceding in mind, the present techniques were tested in attempts to pattern sub-10 μm trenches (with a duty cycle of 50%) to etch depths greater than 300 μm (e.g., greater than 342 μm). Aspects of these studies are illustrated in FIG. 3 where a representation of a silicon wafer 82, processed as described above, is schematically illustrated along with scanning electron micrograph images 120A, 120B illustrating a trench structure formed using the techniques described herein. An aluminum mask and overlying photoresist was patterned on the silicon wafer 82 with equal number of lines/space. Space critical dimensions (CDs) ranged, as shown, from 15 μm, 10 μm, 8 μm, and 4 μm. In this study, the goal was to etch trenches 110 having a depth greater than 300 μm and corresponding aspect ratios greater than 20:1 or 30:1 with an approximately 10 μm space CD or less at ˜50% duty cycle. A maximum trench depth of approximately 342 μm was obtained after a DRIE etch time of approximately 180 minutes. As shown in the images 120, the maximum aspect ratio achieved was approximately 34:1 for 10 μm spacing (i.e., a 342 μm trench depth). Greater than 90% of the initial aluminum mask layer deposited remained after the approximately 180 minute DRIE etch time and, as noted above, the silicon etch depth was approximately 342 μm). The DRIE etch time was essentially limited by equipment/operator availability and total thickness of the starting silicon substrate.

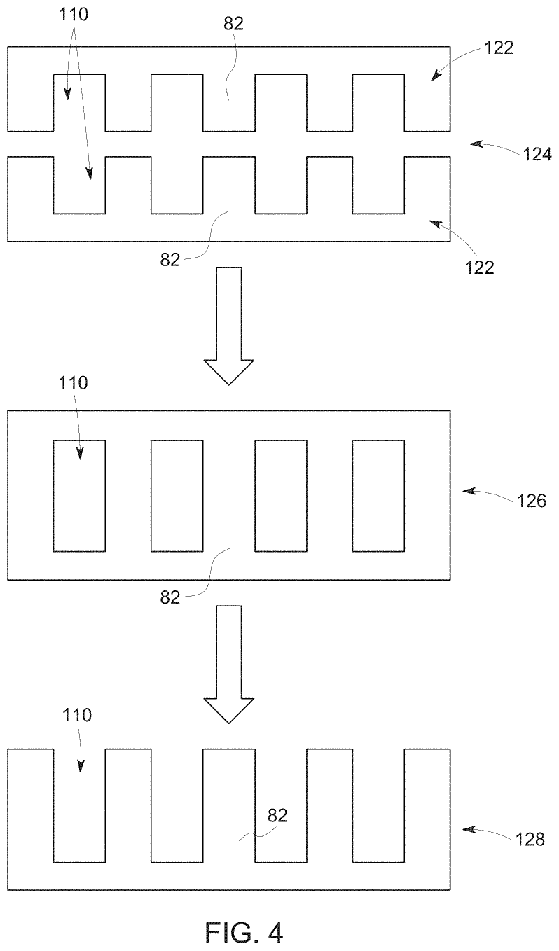

It should also be appreciated that structures (e.g., wafers) in which trench structures 110 have been formed in accordance with this approach may be “stacked” or otherwise assembled together to form trenches having even higher aspect ratios. For example, turning to FIG. 4, two opposing trench structure containing wafers or surfaces 122 may be aligned and overlayed (step 124). The structures may then be fused or joined using conventional silicon processing techniques, as shown in step 126. In the illustrated embodiment, the wafers in which the trenches 110 are formed have been processed to remove aluminum and photoresist before joining, though in other embodiments some aspects of these layers may remain. As shown in step 128, one surface of the joined structure may be etched or otherwise removed to form a new trench structure containing higher-aspect ratio trenches than were present in the initial structures. As may be appreciated, in certain implementations, this process may be repeated using the new structures to continue to achieve even higher aspect ratio trenches, though it should be appreciated that such stacked grating structures may also be formed using other stacking arrangements to achieve a comparable increase in aspect ratio and using the same or similar fabrication methods.

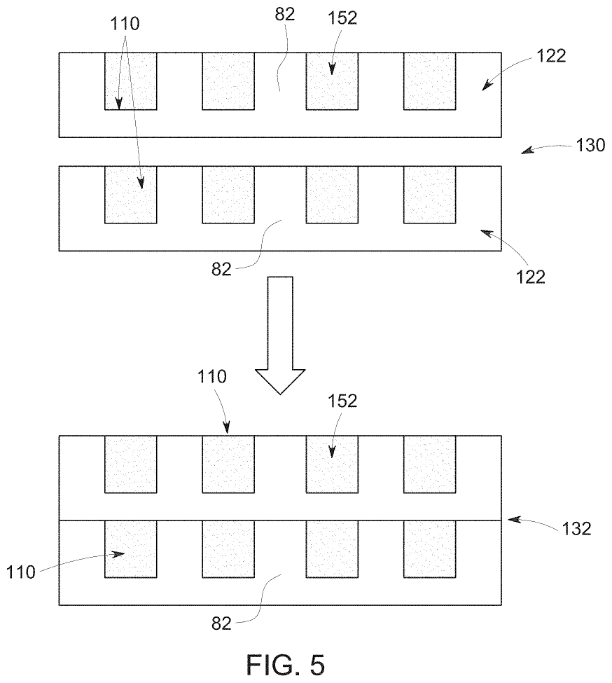

In a further embodiment, the structures (e.g., wafers) in which trench structures 110 have been formed and filled with high Z-metals and may be “stacked” or otherwise assembled together to form trenches that effectively or functionally have even higher aspect ratios for certain applications, such as X-ray based imaging, without removal of the silicon base layer. By way of example, and as discussed in greater detail below, the trench structures 110 may be filled with a nano-metallic powder containing composition 152 (e.g., high Z metal particulates dispersed within a resin matrix). Turning to FIG. 5, two trench structure containing wafers or surfaces 122 may be aligned and overlayed (step 130) while having the same orientation (i.e., trenches facing upward or trenches facing downward. The structures may then be fused or joined using conventional silicon processing techniques, as shown in step 132. In the illustrated embodiment, the wafers in which the trenches 110 are formed have been processed to remove aluminum and photoresist before joining, though in other embodiments some aspects of these layers may remain. In such a structure, due to the effective transparency of the silicon layer to X-rays along with the effective blocking of X-rays with the filled high Z-metal, the resulting structure effectively has higher aspect ratio metallized trenches 110 at defined periods for an imaging application, despite structurally having a break or intervening layer of silicon disposed between the trenches 110. As in the preceding example, in certain implementations this process may be repeated using the new structures to continue to achieve even higher effective aspect ratio metallized trenches.

In certain embodiments it may be further useful to fill the trench structures with a material, such as a metal or high-Z material, to fabricate a device or component. For example, such a structure with filled trenches may be useful as a grating or grid component for use in a medical imaging system (e.g., a phase or absorption grating). In practice, however, it may be difficult to fill a high-aspect ratio trench structure with a metal or metallic element or composition. For example, it may be difficult to get a homogenous or otherwise consistent fill profile of a metal or metallic composition in a high-aspect ratio structure. With this in mind, an alternative approach for filling high-aspect ratio structures is described herein.

For example, in one implementation a metallized grating may be formed by filling the high-aspect ratio trench structures with a composition of nano-particles (e.g., nano-particles of a high-Z material, such as hafnium, tantalum, rhenium, osmium, iridium, platinum, thallium, bismuth, tungsten, lead, gold, and so forth) suspended within a carrier fluid that cures to a solid state, such as an epoxy resin matrix. The process of filling the trench structures with the composition (e.g., a nano-metal ink) may be achieved using various approaches including, but not limited to: squeegeeing, roll printing, screen printing, and so forth.

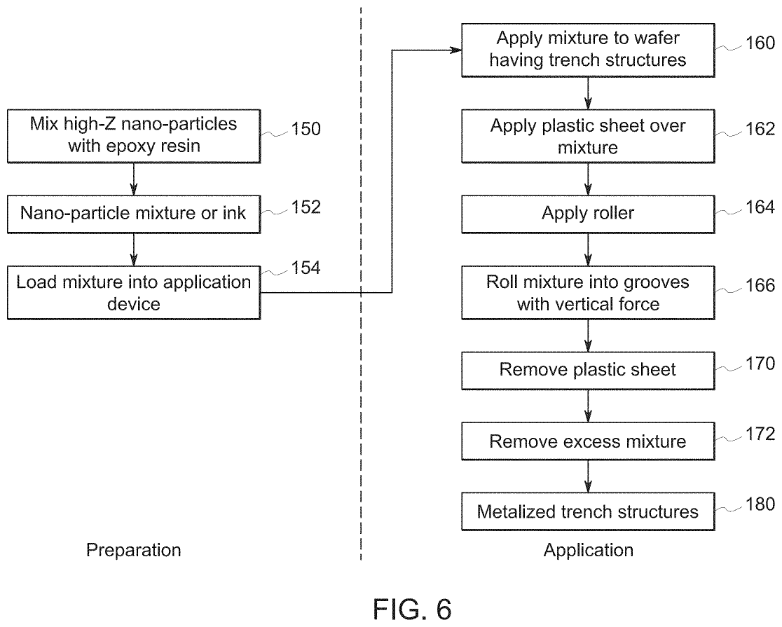

A process flow for one such implementation is provided in FIG. 6. In this example, preparation steps (leftmost) and application steps (rightmost) are both shown. In accordance with this example, a mixture (e.g., a nano-metal ink) is created by combining or mixing (step 150) nano-particles of a high-Z material (e.g., tungsten, lead, gold, and so forth) with a suitable non-solid medium or carrier fluid that can be set or cured to solidity, such as an epoxy resin matrix employing a curing agent or condition. As shown in FIG. 6, the resulting mixture 152 is loaded (step 154) into a suitable application device for dispensing the mixture 152 onto or into one or more high-aspect ratio trench structures, as discussed herein.

By way of providing a real-world preparation example illustrating these steps, in one study the nano-particles comprised tungsten powder of 99.95% purity where the diameter of the tungsten particles is less than 1 μm, such as a tungsten powder. A suitable epoxy resin was employed as the carrier fluid. In this study tungsten powder having the above characteristics was mixed with epoxy resin and a cross-linker to facilitate setting. The resulting mixture was then loaded into a syringe for dispensing, though on a larger scale other suitable application devices may instead be employed.

Turning to the application aspects of the present technique, the loaded application device is used to apply (step 160) the mixture 152 to a surface (e.g., a wafer) in which trench structures or other high-aspect ratio features are formed. In this example a plastic sheet of other deformable membrane or layer with which the mixture 152 will not react is applied (step 162) over the surface on which the mixture 152 is applied. In the depicted example process flow, a roller is applied (step 164) to the plastic sheet and the roller is rolled (step 166) over the surface having trenches or grooves with a corresponding application of vertical force (i.e., downward or toward the surface) to force the mixture 152 into the trenches within the wafer or other structure. As discussed herein, other approaches for applying the mixture 152 within the trenches, such as screen-printing techniques, vacuum fill, injection (ink-jet)-compaction or use of a squeegee, may alternatively be employed.

In the present example process flow, after the mixture 152 is rolled into the grooves or trenches formed in the wafer or other structure, the deformable layer (e.g., plastic sheet) is removed (step 170) and any excess mixture 152 (e.g., mixture that is not within a trench or groove is removed (step 172) from the surface of the wafer, such as by scraping with a sharp or hard edge. The resulting structure has metallized trench structures 180 filled with high-Z nano-particles within the set or hardened mixture deposited within the trenches. Such metallized trench structures 180 may be part of a grating (e.g., a phase or absorption grating) of an imaging system or as part of some other MEMS device.

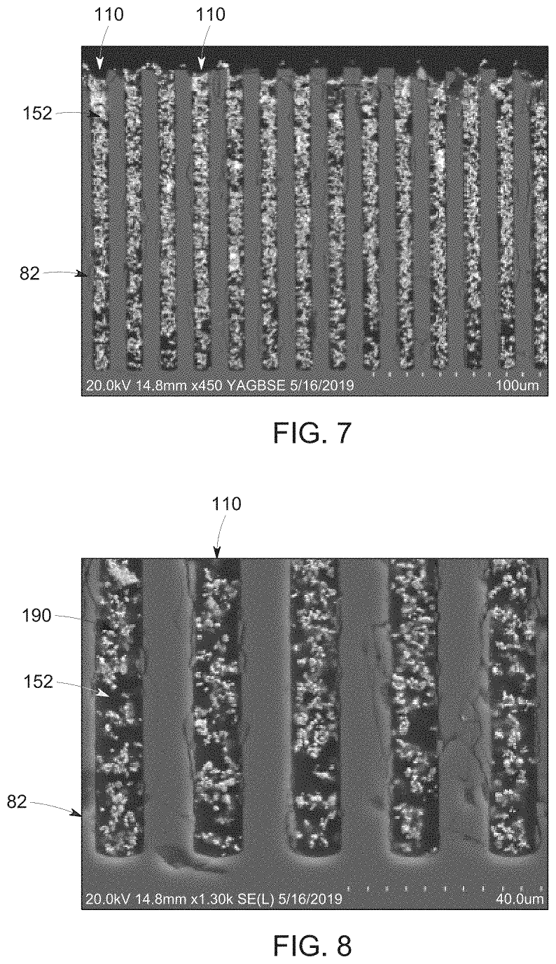

With the preceding in mind, an experimental study was performed to metallize trench structures using a mixture high-Z nano-particles and epoxy resin. In this study, prototype gratings (with a period 20 μm, a duty cycle of 50%, and an aspect ratio >20:1) were filled with tungsten nano-particles suspended in epoxy resin matrices through processes involving squeegeeing and rolling. These filled gratings were characterized through optical microscopy, secondary electron microscopy (SEM), both top-down and cross-sections imaging; energy dispersive X-ray spectroscopy of the SEM micrographs, and X-ray microscopy. Accompanying FIGS. 7-9 are cross-sectional images of metallized trench structures formed in accordance with these processes.

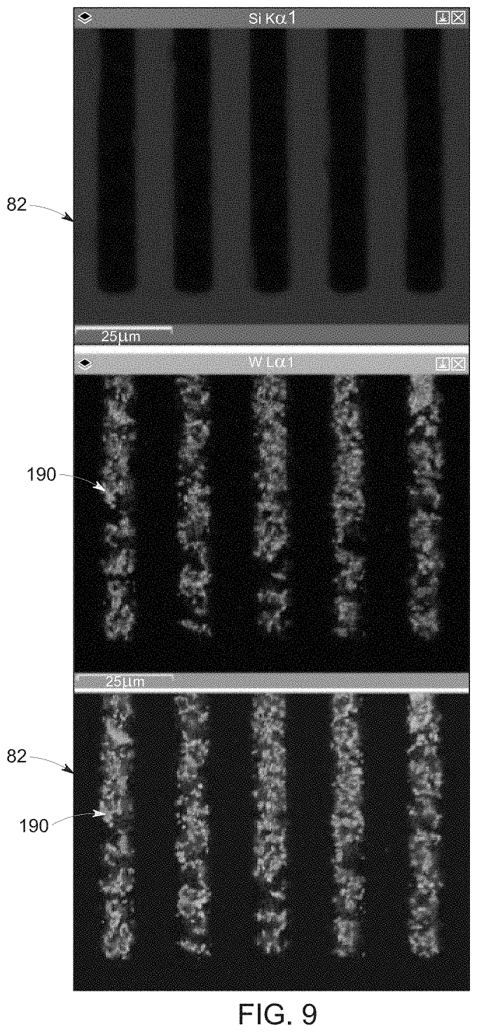

For example, turning to FIG. 7 a high-aspect ratio trench structure is illustrated in a cut-away image generated using backscattered electrons (BSE) in scanning electron microscopy (SEM). In this example, the structure is formed from a silicon wafer 82 and 10 μm trenches 110 were roll-filled filled with a mixture 152 comprising tungsten nano-particles and epoxy resin. A close-up view of this structure is provided in FIG. 8, where discrete tungsten nano-particles 190 can be more readily discerned suspended within the set epoxy that fills the trenches 110. FIG. 9 provides a series of elemental map images of this close up image in the form of a silicon image (uppermost), a tungsten image (middle), and a combined or composite image (bottom). As can be seen, the tungsten nano-particles effectively metallize the trenches in a substantially homogeneous and uniform manner.

Technical effects of the invention include the fabrication of high-aspect ratio (i.e., greater than 20:1) metallized structures for various devices (e.g., X-ray imaging gratings and other trenched and/or segmented gratings, capacitive MEMS, electrostatic MEMS, inertial MEMS, other MEMS structures, Through Silicon Vias (TSVs), FinFETs, Interconnect structures in SOC/CMOS, etc.). Further technical effects include filling such trench structures using a mixture of high-Z nano-particles within an epoxy resin matrix to effectively metallize the trenches. Advantages of the invented method(s) include lower processing steps, reduced equipment costs, higher throughput per unit area of substrate, flexible fabrication across whole range of nano-particle compositions, easier scalability across a range of aspect ratios and substrate sizes.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A method for forming a patterned substrate, comprising:
depositing a mask layer on a substrate;
depositing a photoresist layer on the mask layer;
patterning the photoresist layer to form a pattern;
etching the mask layer through the pattern to expose the substrate; and
etching the substrate through the pattern to form a structure comprising a plurality of trenches having vertical sidewall, wherein the photoresist layer remains on the mask layer during etching of the substrate.

2. The method of claim 1, wherein the mask layer comprises an aluminum layer.

3. The method of claim 1, wherein the substrate comprises a silicon substrate.

4. The method of claim 1, wherein the vertical sidewalls have aspect ratios of 20:1 or greater.

5. The method of claim 1, wherein depositing the mask layer comprises using electron beam (e-beam) evaporation to deposit an aluminum layer.

6. The method of claim 1, wherein the substrate comprises a silicon wafer.

7. The method of claim 1, wherein patterning the photoresist layer comprises photolithographically patterning the photoreist layer.

8. The method of claim 1, wherein the photoresist layer has a thickness of at least 7.5 μm when applied.

9. The method of claim 1, wherein etching the mask layer comprises wet etching an aluminum layer through the pattern.

10. The method of claim 1, wherein etching the substrate comprises performing a deep reactive ion etch of the substrate.

11. The method of claim 1, further comprising:
aligning the plurality of trenches of the structure with a corresponding plurality of trenches of an additional structure such that the plurality of trenches and the corresponding plurality of trenches face one another or are aligned in the same orientation;
joining the structure and the additional structure.

12. The method of claim 11, further comprising;
removing a base surface of the structure to form a secondary structure comprising a second plurality of trenches having aspect ratios greater than those of the structure or the additional structure.

13. The method of claim 1, further comprising:
filling the plurality of trenches with a mixture of high-Z nano-particles and a carrier fluid that cures to a solid state to form a metallized grid structure.

14. The method of claim 13, wherein the high-Z nano-particles comprise at least one of hafnium, tantalum, tungsten, rhenium, osmium, iridium, platinum, gold, mercury, thallium, lead, bismuth, polonium, or depleted uranium.

15. A method for forming a metallized grid structure, comprising:
applying a mixture of high-Z nano-particles and a carrier fluid that cures to a solid state to a substrate comprising a plurality of trenches;
distributing the mixture into the plurality of trenches;
removing excess mixture not in the plurality of trenches from the surface of the substrate; and
curing the carrier fluid to the solid state to form the metallized grid structure.

16. The method of claim 15, wherein the high-Z nano-particles comprise at least one of hafnium, tantalum, tungsten, rhenium, osmium, iridium, platinum, gold, mercury, thallium, lead, bismuth, polonium, or depleted uranium.

17. The method of claim 15, wherein the plurality of trenches have aspect ratios of 20:1 or greater.

18. A grid structure, comprising:
a substrate in which a plurality of trenches are formed; and
a cured carrier fluid disposed within the plurality of trenches, wherein a plurality of nano-particles are suspended within the cured carrier fluid.

19. The grid structure of claim 18, wherein each trench of the plurality of trenches has an aspect ratio of 20:1 or greater.

20. The grid structure of claim 18, wherein the cured carrier fluid comprises an epoxy resin matrix.

21. The grid structure of claim 18, wherein the plurality of nano-particles comprise a high-Z material.

22. The grid structure of claim 18, wherein the plurality of nano-particles comprise at least one of hafnium, tantalum, tungsten, rhenium, osmium, iridium, platinum, gold, mercury, thallium, lead, bismuth, polonium, or depleted uranium.

23. The grid structure of claim 18, wherein the grid structure is a component of an imaging grating, a capacitive MEMS device, an electrostatic MEMS device, a magnetic MEMS device, an electromagnetic MEMS device, a radiofrequency MEMS device, or an inertial MEMS device.
